(19) United States
(12) Patent Application Publication
(10) Pub. No.: US 2012/0155178 A1
(43) Pub. Date: Jun. 21, 2012

(54) SEMICONDUCTOR MEMORY DEVICE

(76) Inventors: Hitoshi OHTA, Yokohama-shi (JP); Mitsuhiro Abe, Kawasaki-shi (JP); Eiji Kozuka, Tokyo (JP); Takatomi Izumi, Motosu-shi (JP)

(21) Appl. No.: 13/235,435

(22) Filed: Sep. 18, 2011

(30) Foreign Application Priority Data
Dec. 17, 2010 (JP) 2010-281383

(51) Int. Cl. G11C 16/26; G11C 16/04; G11C 7/10

(52) U.S. Cl. 365/185.17; 365/189.05

(57) ABSTRACT

According to one embodiment, a semiconductor memory device includes a memory, and a data transfer section configured to perform data transfer from and to the memory, and having a first mode to transfer data with a first bit width and a second mode to transfer data with a second bit width. The data transfer section includes a first latch circuit configured to hold first data read from the memory, a second latch circuit configured to hold second data having the first bit width of the first data in the first mode, and to hold third data having the second bit width of the first data in the second mode, and data bus connecting the first latch circuit to the second latch circuit and shared by the first and second modes.

### CROSS-REFERENCE TO RELATED APPLICATIONS

This application is based upon and claims the benefit of priority from prior Japanese Patent Application No. 2010-281383, filed Dec. 17, 2010, the entire contents of which are incorporated herein by reference.

### FIELD

Embodiments described herein relate generally to a semiconductor memory device.

### BACKGROUND

As a nonvolatile semiconductor memory, a NAND flash memory is known. Data is read from and written to the NAND flash memory by a unit called a page. The page data read from a memory cell array is stored in a page buffer.

The page data stored in the page buffer is transferred with a specific bit width in accordance with various operation modes provided in the NAND flash memory. This requires data bus having a specific bit width, and a large number of latch circuits which hold transfer data.

### BRIEF DESCRIPTION OF THE DRAWINGS

FIG. 1 is a block diagram of a memory system 1 according to a first embodiment;

FIG. 2 is a circuit diagram of a memory cell array 10;

FIG. 3 is a circuit diagram of a data transfer section 17;

FIG. 4 is a circuit diagram of a data transfer section according to a comparative example;

FIG. 5 is an exemplary diagram explaining a data transfer system in OneNAND mode;

FIG. 6 is a timing chart explaining the data transfer system in the OneNAND mode;

FIG. 7 is a block diagram showing a constitution of a NAND sequencer 14;

FIG. 8 is an exemplary diagram explaining a data transfer system according to a comparative example;

FIG. 9 is a timing chart explaining the data transfer system according to the comparative example;

FIG. 10 is a schematic diagram of a memory system 1 according to a second embodiment;

FIG. 11 is an exemplary diagram explaining a program operation in PureNAND mode;

FIG. 12 is a flowchart showing the program operation in the PureNAND mode;

FIG. 13 is an exemplary diagram explaining a reading operation in the PureNAND mode;

FIG. 14 is a flowchart showing a reading operation in the PureNAND mode;

FIG. 15 is a circuit diagram showing an example of a clock generation circuit 14b;

FIG. 16 is a block diagram of a clock generation circuit 80 according to a third embodiment;

FIG. 17 is a diagram explaining a clock for the OneNAND mode;

FIG. 18 is a diagram explaining a clock for the PureNAND mode;

FIG. 19 is a circuit diagram of an input changeover circuit 81 and delay circuits 82 and 85;

FIG. 20 is a circuit diagram of a decoder 83;

FIG. 21 is a diagram explaining a selection signal Sr;

FIG. 22 is a circuit diagram of a selection circuit 84; and

FIG. 23 is a circuit diagram of an output circuit 88.

### DETAILED DESCRIPTION

In general, according to one embodiment, there is provided a semiconductor memory device comprising:

a memory; and

a data transfer section configured to perform data transfer from and to the memory, and having a first mode to transfer data with a first bit width and a second mode to transfer data with a second bit width,

the data transfer section including:

a first latch circuit configured to hold first data read from the memory;

a second latch circuit configured to hold second data having the first bit width of the first data in the first mode, and to hold third data having the second bit width of the first data in the second mode; and

data bus connecting the first latch circuit to the second latch circuit and shared by the first and second modes.

The embodiments will be described hereinafter with reference to the accompanying drawings. In the description which follows, the same or functionally equivalent elements are denoted by the same reference numerals, to thereby simplify the description.

### FIRST EMBODIMENT

### 1. Whole Constitution of Memory System

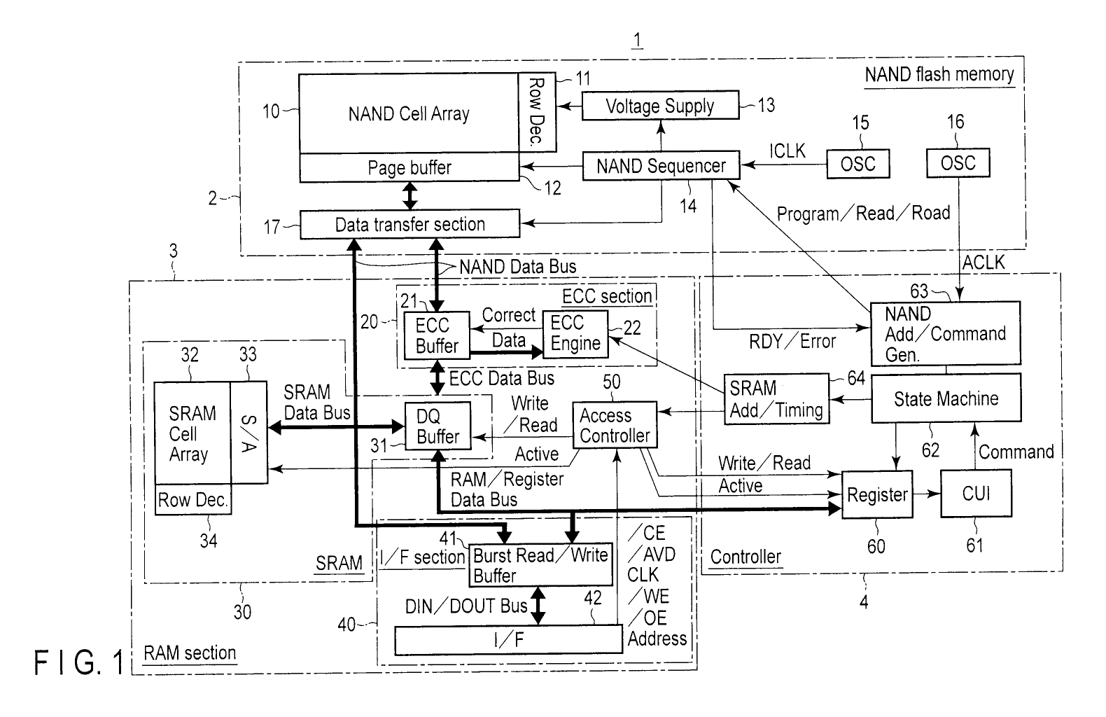

FIG. 1 is a block diagram of a semiconductor memory device (a memory system) 1 according to a first embodiment. The memory system 1 includes a NAND flash memory 2, a RAM section 3, and a controller 4. The NAND flash memory 2, the RAM section 3 and the controller 4 are formed on the same semiconductor substrate, and integrated in one chip. Hereinafter, modules constituting the memory system 1 will be described in detail.

<1-1. NAND Flash Memory 2>

The NAND flash memory 2 serves as a main memory section of the memory system 1. The NAND flash memory 2 includes a memory cell array (NAND Cell Array) 10, a row decoder (Row Dec.) 11, a page buffer 12, a voltage generation circuit (Voltage Supply) 13, a NAND sequencer 14, oscillators (OSC) 15 and 16, and a data transfer section 17.

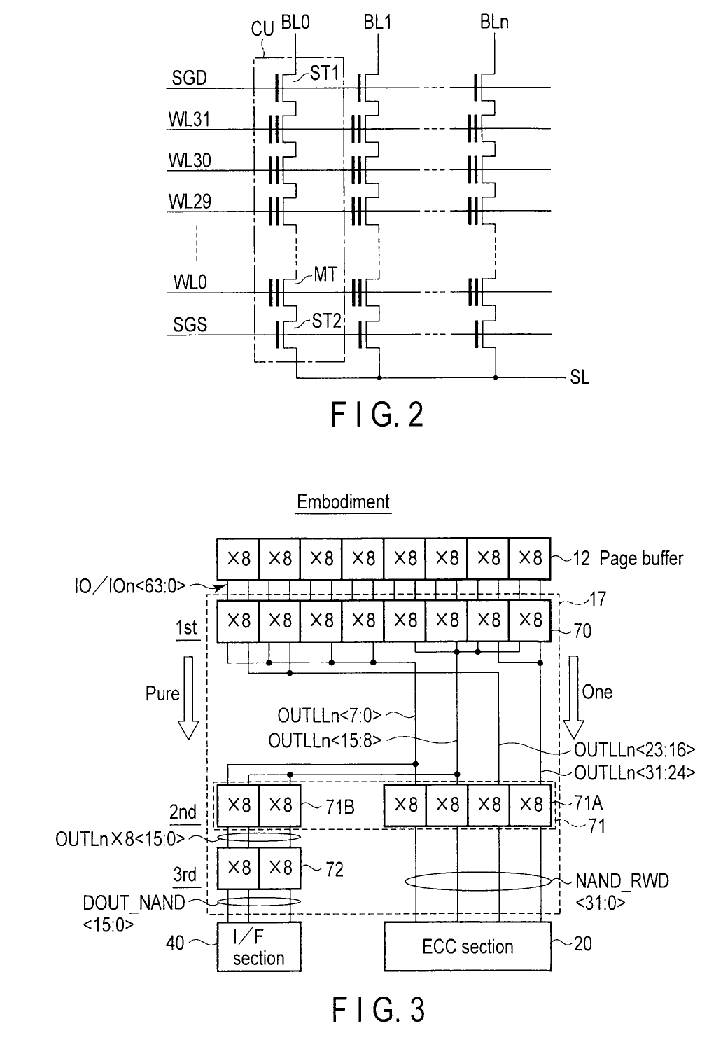

The memory cell array 10 includes memory cell transistors. FIG. 2 is a circuit diagram of the memory cell array 10. The memory cell array 10 includes memory cell units CU. Each of the memory cell units CU is constituted of, for example, 32 memory cell transistors MT, and two selection transistors ST1 and ST2. Each of the memory cell transistors MT includes a laminated gate structure having a charge accumulation layer (e.g. a floating gate electrode) formed on the semiconductor substrate via a gate insulation film, and a control gate electrode formed on the charge accumulation layer via an inter-gate insulation film. The memory cell transistor MT may include a metal oxide nitride oxide silicon (MONOS) structure in which a system to trap electrons is used in a nitride film as the charge accumulation layer.

Current paths of the adjacent memory cell transistors MT are connected in series. Drains at ends of the memory cell transistors MT connected in series are connected to a source of the selection transistor ST1, and the other source of the transistor is connected to a drain of the selection transistor ST2.

The respective control gate electrodes of the memory cell transistors MT in the same row are connected in common to any of word lines WL0 to WL31. The respective gates of the selection transistors ST1 and ST2 in the same row are connected in common to selection gate lines SGD and SGS, respectively. The respective drains of the selection transistor ST1 are connected to any of bit lines BL0 to BLn (n is an integer of 1 or a larger integer). A source of the selection transistor ST2 is connected to a common source line SL.

The memory cell transistors MT connected to the same word line WL constitute a page. Data is collectively written to and read from the memory cell transistors MT in one page. Moreover, pieces of page data are collectively erased, and this deletion unit is called a memory block. FIG. 2 shows only one memory block, but in actual, memory blocks are included in the memory cell array 10.

Each of the memory cell transistors MT can store data of one bit in accordance with, for example, a change of a threshold voltage due to a size of the electrons implanted in the floating gate electrode. Control of the threshold voltage is subdivided, whereby the memory cell transistor MT may store the data of two or more bits.

In FIG. 1, the row decoder 11 selects the word lines WL0 to WL31 and the selection gate lines SGD and SGS during the writing, reading and erasing of the data. Moreover, the row decoder applies a required voltage to the word lines WL0 to WL31 and the selection gate lines SGD and SGS.

The page buffer 12 can hold the data having the same size as that of the page of the memory cell array 10. That is, the page buffer 12 temporarily stores the data of one page read from the memory cell array 10 during the reading, and temporarily stores the data of one page to be written to the memory cell array 10 during the writing. Moreover, the page buffer 12 sends, to the data transfer section 17, the data of 64 bits designated at an address in the page data, and receives the data of 64 bits from the data transfer section 17. Furthermore, the page buffer 12 includes a sense amplifier which writes write data in the memory cell array 10 and reads data from the memory cell array 10.

The voltage generation circuit 13 generates the voltage required for writing, reading and erasing the data, and supplies this voltage to the row decoder 11 or the like.

The NAND sequencer 14 controls an operation of the whole NAND flash memory 2. That is, on receiving various commands from the controller 4, the NAND sequencer 14 executes a sequence of the data writing, reading, erasing and the like in response to this command. Moreover, the sequencer controls the operation of the voltage generation circuit 13 or the page buffer 12 in accordance with this sequence.

The oscillator 15 generates an internal clock ICLK, and supplies the internal clock ICLK to the NAND sequencer 14. The NAND sequencer 14 operates synchronously with the internal clock ICLK. Moreover, the NAND sequencer 14 generates several clock signals from the internal clock ICLK, and supplies the clock signals to the data transfer section 17.

The oscillator 16 generates an internal clock ACLK, and supplies the internal clock ACLK to the controller 4 or the RAM section 3. The internal clock ACLK is a reference clock for operating the controller 4 and the RAM section 3.

The data transfer section 17 controls data transfer between the page buffer 12 and the RAM section 3, and more specifically, the data transfer section 17 controls the data transfer between the page buffer 12 and an ECC section 20, and the data transfer between the page buffer 12 and an I/F section 40. For this control, the data transfer section 17 includes buses and latch circuits, and further receives the clock from the sequencer 14. A specific constitution of the data transfer section 17 will be described later.

<1-2. RAM Section 3>

Next, a constitution of the RAM section 3 shown in FIG. 1 will be described. The RAM section 3 includes the ECC section 20, a static random access memory (SRAM) 30, the interface section (the I/F section) 40, and an access controller 50.

In the memory system 1, the NAND flash memory 2 serves as a main memory section, and the SRAM 30 of the RAM section 3 serves as a memory buffer. Therefore, when the data is read from the NAND flash memory 2 to the outside, the data read from the memory cell array 10 is first stored in the SRAM 30 of the RAM section 3 via the page buffer 12. Afterward, the data in the SRAM 30 is transferred to the interface section 40, and output to the outside. On the other hand, when the data is stored in the NAND flash memory 2, the data input from the outside is first stored in the SRAM 30 via the interface section 40. Afterward, the data in the SRAM 30 is transferred to the page buffer 12, and written to the memory cell array 10.

In the following description, an operation of reading the data from the memory cell array 10 and transferring the data to the SRAM 30 via the page buffer 12 is called “load” of the data. Moreover, an operation of transferring the data in the SRAM 30 to an interface 42 via a buffer 41 in the interface section 40 is called “read” of the data.

Moreover, an operation of transferring the data to be stored in the NAND flash memory 2, from the interface 42 to the SRAM 30 via the buffer 41 is called “write” of the data. Moreover, an operation of writing the data of the SRAM 30 in the memory cell array 10 via the page buffer 12 is called “program” of the data.

<1-2-1. ECC Section 20>

The ECC section 20 performs error checking and correcting (ECC) processing. That is, during the loading, the data read from the NAND flash memory 2 is subjected to the error checking and correcting. On the other hand, during the programming, a parity is generated concerning the data to be programmed. The ECC section 20 includes an ECC buffer 21 and an ECC engine 22.

The ECC buffer 21 is connected to the data transfer section 17 by a NAND data bus, and connected to the SRAM 30 by an ECC data bus. The ECC buffer 21 temporarily stores the data for the ECC processing (the error correcting during the loading and the parity generation during the programming). The ECC buffer 21 is connected to the data transfer section 17 by data buses each having a width of 32 bits. The ECC engine 22 performs the ECC processing by use of the data held in the ECC buffer 21. Specifically, the ECC engine 22 corrects the error of the data (Data) input into the ECC buffer 21, and outputs the corrected data (Correct) to the ECC buffer 21 again.

<1-2-2. SRAM 30>

The SRAM 30 serves as a buffer memory for the NAND flash memory 2. The SRAM 30 includes a DQ buffer 31, a memory cell array (SRAM Cell Array) 32, a sense amplifier (S/A) 33, and a row decoder (Row Dec.) 34. The DQ buffer 31 temporarily stores data to the memory cell array 32 or data from the memory cell array 32 during the loading, reading, writing and programming of the data. The memory cell array 32 includes SRAM cells. The sense amplifier 33 detects and amplifies the data from the SRAM cells, or serves as a load during the writing of the data of the DQ buffer 31 in the SRAM cells. The row decoder 34 selects a specific word line in the memory cell array 32.

<1-2-3. Interface Section 40>

The interface section 40 includes the burst read/write buffer 41 and the interface (I/F) 42.

The interface 42 receives and transmits various signals, such as data, a control signal and an address, from and to an external host apparatus of the memory system 1. Examples of the control signal include a chip enable signal /CE for enabling the whole memory system 1, an address valid signal /AVD for latching the address, a clock CLK for burst reading, a write enable signal /WE for enabling a writing operation, and an output enable signal /OE for enabling the output of the data to the outside. Moreover, the interface 42 sends, to the access controller 50, a control signal concerning a writing request and a reading request from the host apparatus.

The buffer 41 is connected to the interface 42 by, for example, DIN/DOUT bus having a width of 16 bits. The buffer 41 temporarily stores the data, for the data reading and writing.

<1-2-4. Access Controller 50>

The access controller 50 receives the control signal and the address from the interface 42. Moreover, the access controller controls the SRAM 30 and the controller 4 so as to execute an operation which satisfies the request of the host apparatus. Specifically, the access controller 50 brings, into an active state, one of the SRAM 30 and a register 60 of the controller 4 which will be described later, in response to the request of the host apparatus. Moreover, the access controller issues a data write or read command (Write/Read) for the SRAM 30 or the register 60. By these control operations, the SRAM 30 and the controller 4 start operations.

<1-3. Controller 4>

The controller 4 controls the whole operation of the memory system 1. The controller 4 includes the register 60, a command user interface (CUI) 61, a state machine 62, a NAND address/command generation circuit (NAND Add/Command Gen.) 63, and an SRAM address/timing generation circuit (SRAM Add/Timing) 64.

The register 60 is used to set an operation state of a function in response to the command from the access controller 50. Specifically, the register 60 holds, for example, the read command or the write command.

The command user interface 61 recognizes that the function execution command has been given to the memory system 1, when a predetermined command is held in the register 60. Then, the interface sends an internal command signal (Command) to the state machine 62.

The state machine 62 controls a sequence operation in the memory system 1 on the basis of the internal command signal given from the command user interface 61. The state machine 62 supports a large number of functions including writing, reading and erasing functions. The state machine 62 controls the operations of the NAND flash memory 2 and the RAM section 3 so as to execute these functions.

The address/command generation circuit 63 controls the operation of the NAND flash memory 2 on the basis of the control of the state machine 62. Specifically, the circuit generates an address, a command (Write/Read/Load) or the like, and sends the address, the command or the like to the NAND flash memory 2. The address/command generation circuit 63 outputs the address or the command synchronously with the internal clock ACLK generated by the oscillator 16.

The address/timing generation circuit 64 controls the operation of the RAM section 3 on the basis of the control of the state machine 62. Specifically, the circuit issues an address or a command required in the RAM section 3, and sends the address or the command to the access controller 50 and the ECC engine 22.

<1-4. Operation of Memory System 1>

Next, an operation of the memory system 1 will be described.

The memory system 1 has a first operation mode (referred to as OneNAND (registered trademark) mode) to transfer the data between the NAND flash memory 2 and the host apparatus via the SRAM 30 and a second operation mode (referred to as PureNAND mode) in which the transfer of the data between the NAND flash memory 2 and the host apparatus is not performed via the SRAM 30. That is, in the PureNAND mode, the data from the NAND flash memory 2 is directly sent to the I/F section 40, and the data from the host apparatus (the data from the I/F section 40) is directly sent to the NAND flash memory 2.

The PureNAND mode and the OneNAND mode have different data transfer systems and, accordingly, have different operation definitions. The operation in the OneNAND mode is defined as described above. In the PureNAND mode, the data transfer via the SRAM 30 is not performed. Therefore, in the PureNAND mode, the reading operation, the programming operation (referred to as the writing operation sometimes) and the erasing operation are executed in the same manner as in the conventional NAND flash memory.

When the host apparatus stores the data in the NAND flash memory 2 in the OneNAND mode, the data is first stored in the SRAM 30 in accordance with the write command and the address of the SRAM 30 from the host apparatus. Afterward, the data stored in the SRAM 30 is written collectively by the page unit in the NAND flash memory 2 in accordance with the program command and the address of the NAND flash memory 2 from the host apparatus.

Moreover, when the host apparatus reads the data from the NAND flash memory 2 in the OneNAND mode, the data is first read from the NAND flash memory 2 and stored in the SRAM 30 in accordance with the load command, the address of the NAND flash memory 2 and the address of the SRAM 30 from the host apparatus. Afterward, the data held in the SRAM 30 is sent to the host apparatus via the interface section 40 in accordance with the read command and the address of the SRAM 30 from the host apparatus.

On the other hand, when the host apparatus stores the data in the NAND flash memory 2 in the PureNAND mode, the data input into the interface section 40 is written collectively by the page unit to the NAND flash memory 2 in accordance with the program command and the address of the NAND flash memory 2 from the host apparatus.

Moreover, when the host apparatus reads the data from the NAND flash memory 2 in the PureNAND mode, the data is read from the NAND flash memory 2, and sent to the host apparatus via the interface section 40 in accordance with the read command and the address of the NAND flash memory 2 from the host apparatus.

### 2. Data Transfer Section 17

Next, a constitution and an operation of the data transfer section 17 will be described. FIG. 3 is a circuit diagram of the data transfer section 17. The OneNAND mode and the PureNAND mode have different bit widths during the data transfer. Specifically, in the OneNAND mode, the data transfer section 17 executes the data transfer by a unit of, for example, 32 bits. Moreover, in the PureNAND mode, the data transfer section 17 executes the data transfer by a unit of, for example, 16 bits (or 8 bits).

The data transfer section 17 includes a first latch circuit 70, a second latch circuit 71 (including 71A and 71B), a third latch circuit 72, and data buses. The first latch circuit 70 is a latch shared by the OneNAND mode and the PureNAND mode. The second latch circuit 71A is a latch for the OneNAND mode. The second latch circuit 71B and the third latch circuit 72 are latches for the PureNAND mode. The first latch circuit 70 holds data of 64 bits. The second latch circuit 71A holds data of 32 bits. The second latch circuit 71B holds data of 16 bits. The third latch circuit 72 holds data of 16 bits. It is to be noted that a quadrangle of the latch circuit shown in FIG. 3 indicates the latch which holds the data of 8 bits, and in the following description, the quadrangle is called a latch.

One end of the first latch circuit 70 is connected to the page buffer 12 via a data bus IO/IOn <63:0>. FIG. 3 shows an extracted page buffer for 64 bits designated at the address. In actual, the page buffer 12 has a larger capacity than in FIG. 3.

The other ends of latches for 16 bits (e.g. third and fourth latches from the left) in the first latch circuit 70 are connected to one end of a latch for 8 bits (e.g. the leftmost latch) in the second latch circuit 71A via an 8-bits data bus OUTLLn <7:0>. The other ends of latches for 16 bits (e.g. third and fourth latches from the right) in the first latch circuit 70 are connected to one end of a latch for 8 bits (e.g. the second latch from the left) in the second latch circuit 71A via an 8-bits data bus OUTLLn <15:8>.

The other ends of latches for 16 bits (e.g. two latches from the left) in the first latch circuit 70 are connected to one end of a latch for 8 bits (e.g. the second latch from the right) in the second latch circuit 71A via an 8-bits data bus OUTLLn <23:16>. The other ends of latches for 16 bits (e.g. two latches from the right) in the first latch circuit 70 are connected to one end of a latch for 8 bits (e.g. the rightmost latch) in the second latch circuit 71A via an 8-bits data bus OUTLLn <31:24>.

The other end of the second latch circuit 71A is connected to the ECC section 20 via a 32-bits bus NAND_RWD <31:0>.

Moreover, the other ends of latches for 32 bits (e.g. four latches from the left) in the first latch circuit 70 are connected to one end of a latch for 8 bits (e.g. the left latch) in the second latch circuit 71B via the 8-bits data bus OUTLLn <7:0>. The other ends of latches for 32 bits (e.g. four latches from the right) in the first latch circuit 70 are connected to one end of the second latch circuit 71B via the 8-bits data bus OUTLLn <15:8>.

The other end of the second latch circuit 71B is connected to one end of the third latch circuit 72 via a 16-bits data bus OUTLnX8 <15:0>. The other end of the third latch circuit 72 is connected to the interface section 40 via a 16-bits data bus DOUT_NAND <15:0>.

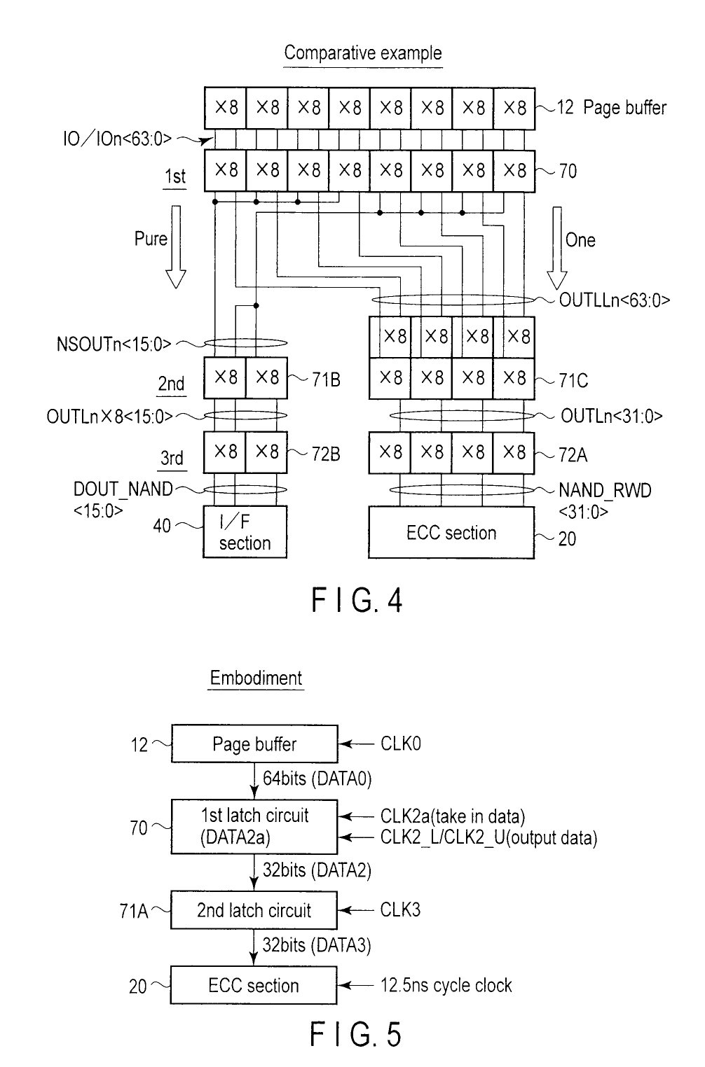

FIG. 4 is a circuit diagram of a data transfer section according to a comparative example. In the comparative example, buses are prepared separately for OneNAND mode and PureNAND mode. That is, a first latch circuit 70 is connected to a second latch circuit 71C via a data bus OUTLLn <63:0> for the OneNAND mode, and connected to a second latch circuit 71B via a data bus NSOUTn <15:0> for the PureNAND mode. The second latch circuit 71C is connected to a third latch circuit 72A via a data bus OUTLn <31:0>. The third latch circuit 72A is connected to an ECC section 20 via a data bus NAND_RWD <31:0>. Moreover, the second latch circuit 71B is connected to an interface section 40 via a third latch circuit 72B and a data bus DOUT_NAND <15:0>.

FIG. 3 is compared with FIG. 4. In the present embodiment, the data buses between the first latch circuit 70 and the second latch circuit 71 are shared by the OneNAND mode and the PureNAND mode, whereby the number of the buses is noticeably decreased from 80 to 32. Moreover, unlike the comparative example, the size of the second latch circuit 71A for the OneNAND mode is decreased to a size for 32 bits, and the third latch circuit for the OneNAND mode is deleted. In consequence, the size of the data transfer section 17 can noticeably be decreased.

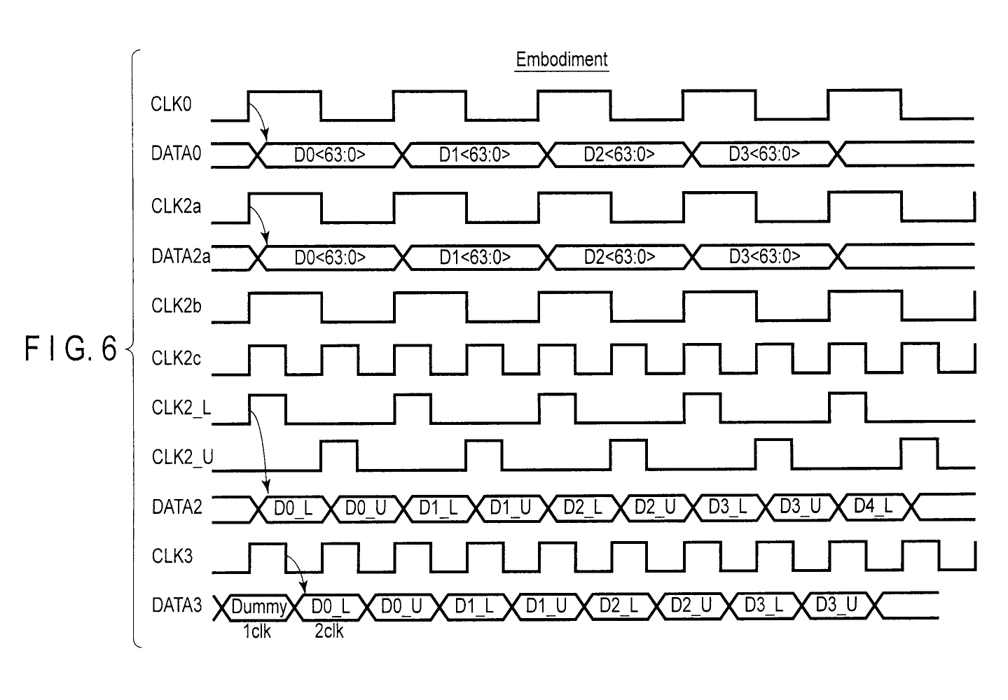

FIG. 5 is an exemplary diagram explaining a data transfer system in the OneNAND mode. FIG. 6 is a timing chart explaining the data transfer system in the OneNAND mode.

The OneNAND mode of the present embodiment is a data transfer system in two stages of “the page buffer (64 bits)→the first latch circuit (64→32 bits)→the second latch circuit (32 bits)”. The page buffer 12 receives a clock CLK0 with a cycle of 25 ns, and outputs data DATA0 by a unit of 64 bits synchronously with rising of the clock CLK0.

The first latch circuit 70 receives a clock CLK2a with a cycle of 25 ns, and takes in data DATA2a by a unit of 64 bits synchronously with the rising of the clock CLK2a. Furthermore, the first latch circuit 70 receives clocks CLK2_L and CLK2_U, and outputs data DATA2 by a unit of 32 bits synchronously with the rising of the clocks CLK2_L and CLK2_U.

Specifically, the first latch circuit 70 outputs lower data D0_L of 32 bits in 64-bits data D0 <63:0> synchronously with the rising of the clock CLK2_L. Next, the first latch circuit 70 outputs upper data D0_U of 32 bits in the 64-bits data D0 <63:0> synchronously with the rising of the clock CLK2_U. Clocks CLK2b and CLK2c of FIG. 6 are clocks for generating the clocks CLK2_L and CLK2_U. The clock CLK2b is a clock with a cycle of 25 ns, and the clock CLK2c is a clock with a cycle of 12.5 ns.

The second latch circuit 71A receives a clock CLK3 with a cycle of 12.5 ns, and outputs data DATA3 by a unit of 32 bits synchronously with falling of the clock CLK3. The ECC section 20 receives the data by a unit of 32 bits from the data transfer section 17 synchronously with the rising of the clock with a cycle of 12.5 ns.

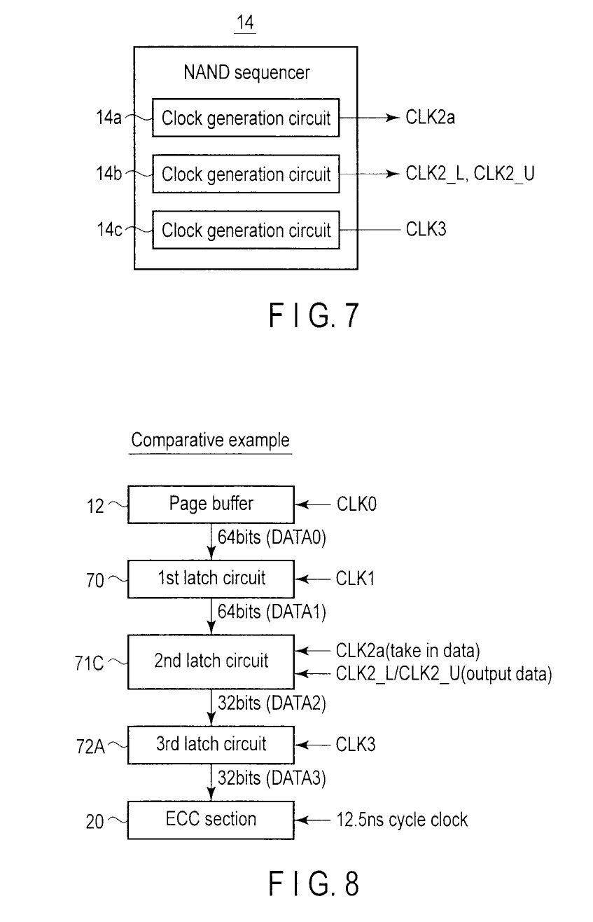

Various clocks shown in FIG. 6 are supplied from the NAND sequencer 14 to the data transfer section 17. FIG. 7 is a block diagram showing a constitution of the NAND sequencer 14. For example, the clock CLK0 is generated by the oscillator 15. The clock CLK2a is generated by a clock generation circuit 14a. The clocks CLK2_L and CLK2_U are generated by a clock generation circuit 14b. The clock CLK3 is generated by a clock generation circuit 14c.

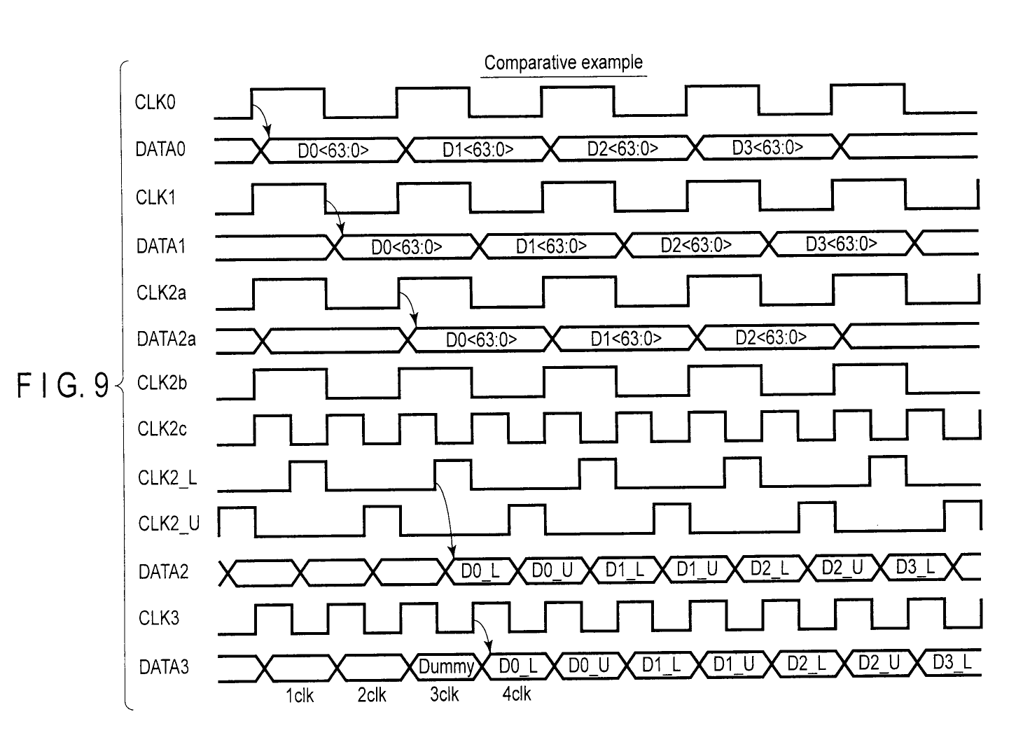

FIG. 8 is an exemplary diagram explaining a data transfer system according to a comparative example. FIG. 9 is a timing chart explaining the data transfer system according to the comparative example. The comparative example is a data transfer system in three stages of “a page buffer (64 bits)→a first latch circuit (64 bits)→a second latch circuit (64→32 bits)→a third latch circuit (32 bits)”.

The first latch circuit 70 executes a data pre-reading operation called prefetch. The first latch circuit 70 receives a clock CLK1 with a cycle of 25 ns, and outputs data DATA1 by a unit of 64 bits synchronously with falling of the clock CLK1.

The second latch circuit 71C receives clocks CLK2_L and CLK2_U with a cycle of 12.5 ns, and outputs data DATA2 by a unit of 32 bits synchronously with rising of the clocks CLK2_L and CLK2_U. The third latch circuit 72A receives a clock CLK3 with a cycle of 12.5 ns, and outputs data DATA3 by a unit of 32 bits synchronously with the rising of the clock CLK3.

In the present embodiment, the prefetch of the comparative example is not performed, and the first latch circuit 70 converts a bit width from 64 bits to 32 bits. Therefore, even when the numbers of the buses and the latch circuits are decreased, the memory system 1 can be realized in the OneNAND mode. Moreover, FIG. 6 is compared with FIG. 9. In the comparative example, data D0_L is transferred to the ECC section 20 at the fourth pulse of the clock CLK3, whereas in the present embodiment, the data D0_L can be transferred to the ECC section 20 at the second pulse of the clock CLK3.

It is to be noted that in an operation of transferring the data from the ECC section 20 to the page buffer 12 via the data transfer section 17, the flow of FIG. 5 is reversed. Moreover, the conversion of the bit width is not required in the PureNAND mode, and hence the data transfer is performed with the same clock (e.g. the clock with a cycle of 25 nm) by the first latch circuit 70, the second latch circuit 71B, and the third latch circuit 72.

### EFFECT

In the first embodiment described above in detail, the controller 4 executes two types of operation modes (the OneNAND mode and the PureNAND mode) having different bit widths during the data transfer. The OneNAND mode is an operation mode to transfer the data between the NAND flash memory 2 and the host apparatus via the SRAM 30, and in this operation mode, the data transfer section 17 is in charge of the data transfer between the page buffer 12 and the ECC section 20. The PureNAND mode is an operation mode in which the transfer of the data between the NAND flash memory 2 and the host apparatus is not performed via the SRAM 30, and in this operation mode, the data transfer section 17 is in charge of the data transfer between the page buffer 12 and the interface section 40. Moreover, the data transfer section 17 shares the data bus by the OneNAND mode and the PureNAND mode. Furthermore, the data transfer section 17 converts the bit width from 64 bits to 32 bits to perform the data transfer in a first stage of a latch operation.

Therefore, according to the first embodiment, the number of the data buses provided between the page buffer 12 and the ECC section 20 can noticeably be decreased. In consequence, a chip area can be reduced.

Moreover, when the data transfer system of the data transfer section 17 is changed in accordance with the decrease of the number of the data buses, the number of the latch circuits included in the data transfer section 17 can be decreased. In consequence, the chip area can be reduced.

Furthermore, the data transfer can correctly be realized without performing the prefetch in the OneNAND mode. In consequence, a data transfer speed can be enhanced.

### Second Embodiment

OneNAND mode and PureNAND mode have different data transfer systems, and hence an ECC section 20 is designed so as to be optimum for a flow of data for the OneNAND mode. A second embodiment is a constitution example in which the ECC section 20 provided for the OneNAND mode can be used in the PureNAND mode.

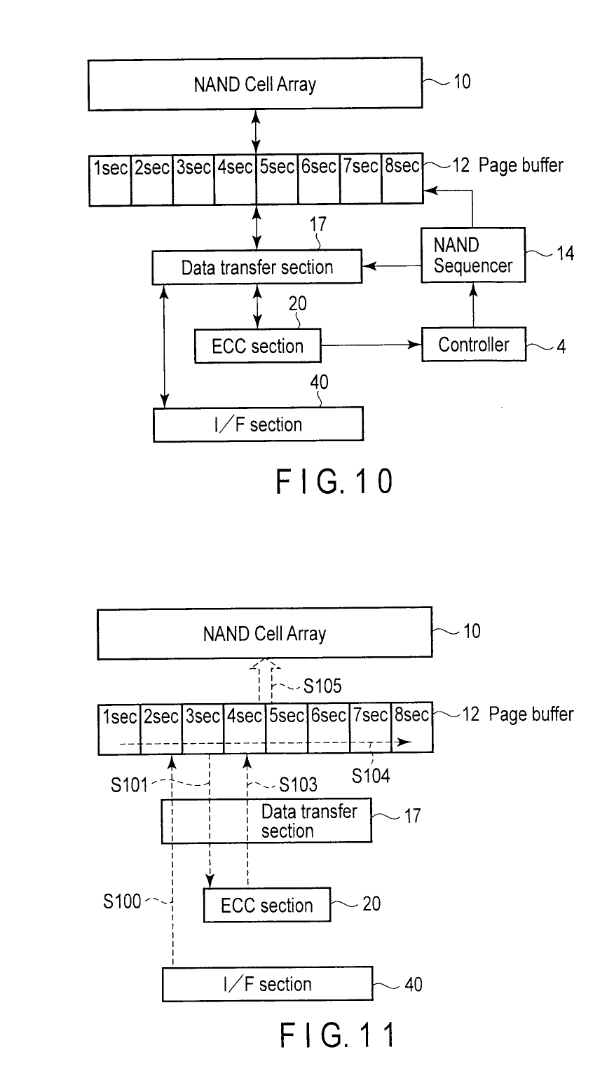

FIG. 10 is a schematic diagram of a memory system 1 according to a second embodiment. FIG. 10 shows blocks (a controller 4, a memory cell array (NAND Cell Array) 10, a page buffer 12, a NAND sequencer 14, a data transfer section 17, the ECC section 20 and an interface section 40) extracted from the block diagram of FIG. 1 and concerned with an error correcting operation in the PureNAND mode. A constitution of blocks other than the blocks shown in FIG. 10 is the same as that of FIG. 1.

The page buffer 12 includes eight sectors (1 sec to 8 sec) each having a size of, for example, 512 bytes, and a size of the buffer is “512 bytes×8=4096 bytes (=4 Kbytes with the proviso that K is 1024)”. Parity generation and error correction are performed for each sector.

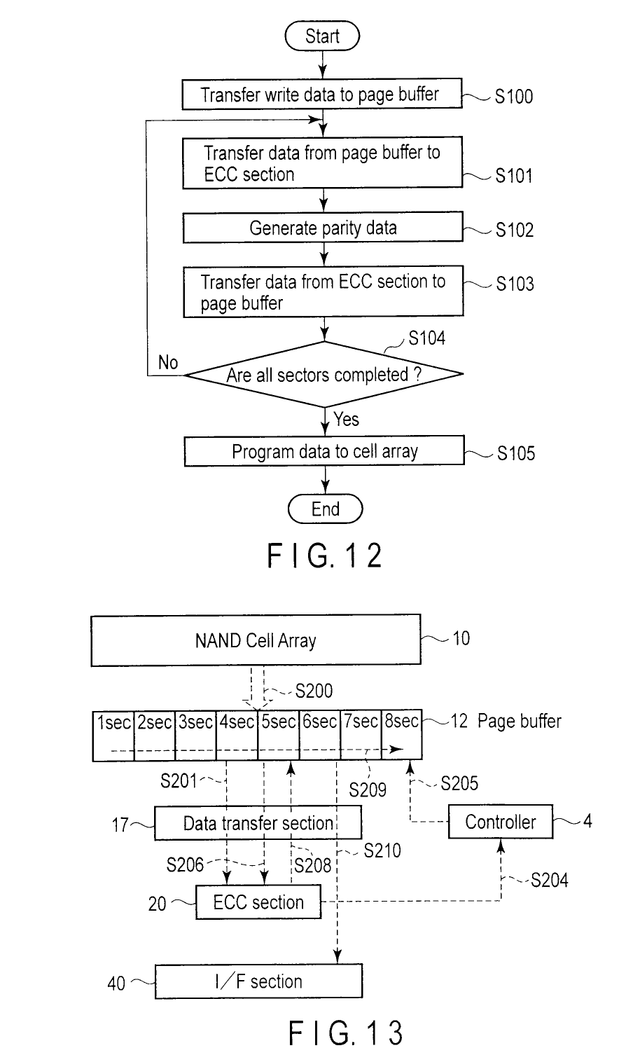

First, there will be described an operation of programming write data from a host apparatus to the memory cell array 10 in the PureNAND mode. FIG. 11 is an exemplary diagram explaining the program operation in the PureNAND mode. FIG. 12 is a flowchart showing the program operation in the PureNAND mode.

The interface section 40 receives, from the host apparatus, a program command, an address and the write data for one page. Next, the controller 4 enters the PureNAND mode. Then, the data transfer section 17 transfers the write data from the interface section 40 to the page buffer 12 (step S100).

Next, the controller 4 transfers data of the first sector to the ECC section 20 via the data transfer section 17 (step S101). At this time, the controller 4 switches to the OneNAND mode, and a clock simultaneously switches to a clock for use in the OneNAND mode. Then, the controller 4 executes data transfer between the page buffer 12 and the ECC section 20 by a unit of 32 bits.

Next, the ECC section 20 generates parity data for the data of the first sector (step S102). Next, the ECC section 20 transfers (writes back) the write data and the parity data to the page buffer 12 (step S103). Next, the controller 4 repeats the steps S101 to S103 until the data transfer of the eighth sector is completed (step S104). Afterward, the controller 4 returns to the PureNAND mode.

Next, the NAND sequencer 14 programs the data of the page buffer 12 to the memory cell array 10 (step S105).

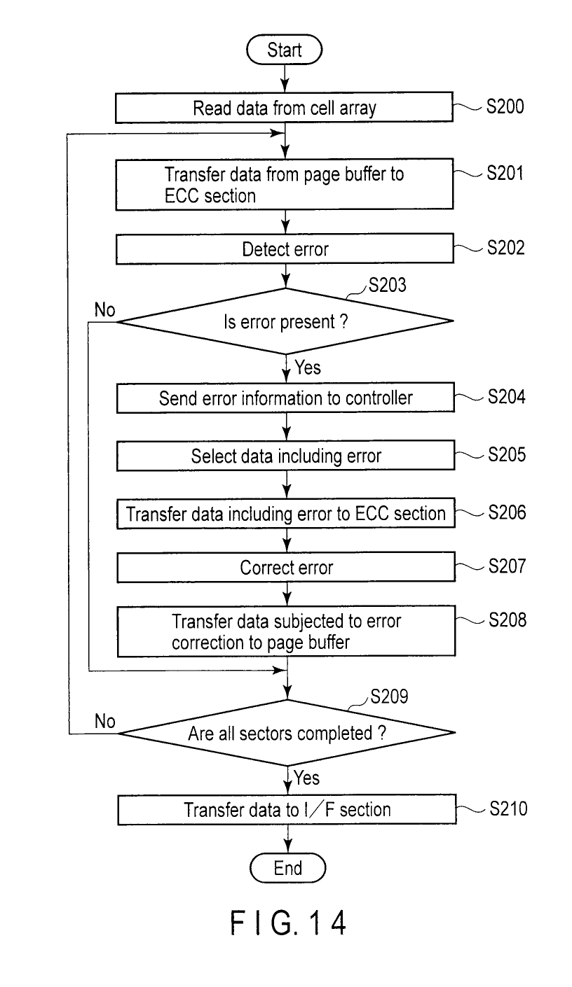

Next, there will be described an operation of reading the data from the memory cell array 10 in the PureNAND mode. FIG. 13 is an exemplary diagram explaining the reading operation in the PureNAND mode. FIG. 14 is a flowchart showing the reading operation in the PureNAND mode.

The interface section 40 receives a read command and an address from the host apparatus. Next, the controller 4 enters the PureNAND mode. Then, the page buffer 12 reads the data from the memory cell array 10 (step S200), and stores the read data.

Next, the controller 4 transfers the data of the first sector from the page buffer 12 to the ECC section 20 via the data transfer section 17 (step S201). At this time, the controller 4 switches to the OneNAND mode, and the clock simultaneously switches to a clock for use in the OneNAND mode. Then, the controller 4 executes the data transfer between the page buffer 12 and the ECC section 20 by a unit of 32 bits.

Next, the ECC section 20 detects an error in the data of the first sector (step S202). When the error is present in the data of the first sector (step S203), the ECC section 20 sends error information (an error address and a signal LOWERR/UPERR) to the controller 4 (step S204). The signal LOWERR/UPERR is information indicating whether 32-bits data including the error is lower data or upper data of 64-bits data.

Next, the data transfer section 17 transfers the 32-bits data including the error from the page buffer 12 to the ECC section 20. Specifically, the NAND sequencer 14 activates a column selection signal CSL corresponding to the error address under the control of the controller 4. The column selection signal CSL is sent to the page buffer 12, and the page buffer 12 outputs the 32-bits data corresponding to the column selection signal CSL (step S205).

During data transfer from the page buffer 12 to the ECC section 20, the data transfer section 17 judges whether the 32-bits data including the error is the lower data or the upper data. In a load operation of the OneNAND mode shown in FIG. 6, the data transfer starts from a lower clock CLK2_L, and 132 clocks are repeated as in “the lower data→the upper data→the lower data→the upper data . . . ” to transfer data of 512 bytes. A data transfer operation during the error correction is basically the same as the load operation, and the NAND sequencer 14 supplies, to the data transfer section 17, a clock required for transferring the 32-bits data including the error.

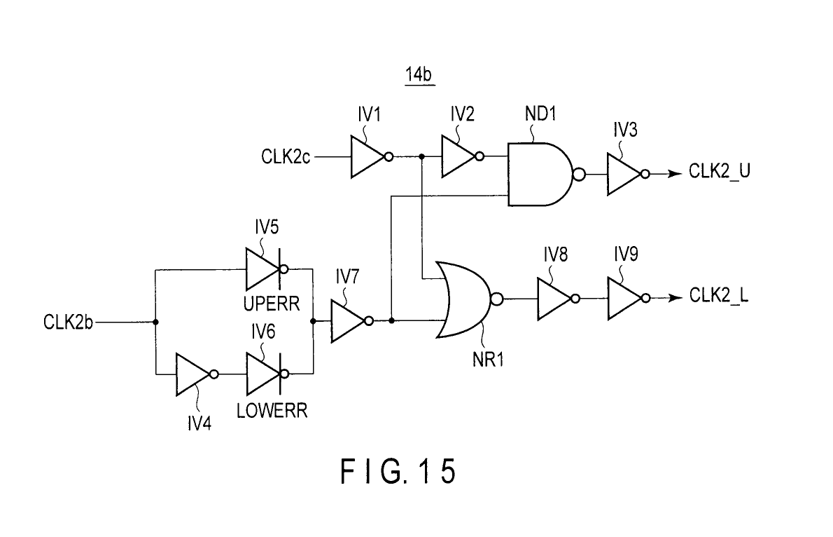

When the data is transferred during the error correction and the error is present in the lower data, LOWERR=1/UPERR=0, whereby the only lower clock CLK2_L is operated. On the other hand, when the error is present in the upper data, LOWERR=0/UPERR=1, whereby an only upper clock CLK2_U is operated. An example of a clock generation circuit 14b which generates the clocks CLK2_L and CLK2_U is shown in FIG. 15.

A clock CLK2c is supplied to an input of an inverter circuit IV1. An output of the inverter circuit IV1 is connected to a first input of a NAND circuit ND1 via an inverter circuit IV2, and connected to a first input of an NOR circuit NR1.

A clock CLK2b is supplied to inputs of an inverter circuit IV4 and a clocked inverter circuit IV5. An output of the clocked inverter circuit IV5 is connected to an input of an inverter circuit IV7. An output of the inverter circuit IV4 is connected to the input of the inverter circuit IV7 via a clocked inverter circuit IV6. An output of the inverter circuit IV7 is connected to second inputs of the NAND circuit ND1 and the NOR circuit NR1. The clocked inverter circuit IV5 operates, when the signal UPERR=1. The clocked inverter circuit IV6 operates, when the signal LOWERR=1.

An output of the NAND circuit ND1 is connected to an input of an inverter circuit IV3, and the inverter circuit IV3 outputs the clock CLK2_U. An output of the NOR circuit NR1 is connected to an input of an inverter circuit IV9 via an inverter circuit IV8. The inverter circuit IV9 outputs the clock CLK2_L.

In the clock generation circuit 14b constituted in this manner, when the 32-bits data selected by the column selection signal CSL is transferred, the only lower clock CLK2_L operates at the time of LOWERR=1, and the only upper clock CLK2_U operates at the time of UPERR=1. In consequence, when the data transfer section 17 receives the clock CLK2_L or CLK2_U, the 32-bits data selected by the column selection signal CSL can be transferred to the ECC section 20.

Next, when the 32-bits data including the error is transferred to the ECC section 20 (step S206), the ECC section 20 corrects the error (step S207). Next, the data transfer section 17 transfers the 32-bits data subjected to the error correction from the ECC section 20 to the page buffer 12 (writes back) (step S208). Clock control in the step S208 is the same as in the step S206.

Next, the controller 4 repeats the steps S201 to S208 until the data transfer of the eighth sector is completed (step S209). Afterward, the controller 4 returns to the PureNAND mode.

Next, the data transfer section 17 transfers the data of the page buffer 12 to the interface section 40 by a unit of 8 bits or 16 bits (step S210). Then, the data transferred to the interface section 40 is output to the host apparatus.

As described above in detail, according to the second embodiment, the error correction can be realized by using the ECC section 20 provided for the OneNAND mode, when the data is transferred in the PureNAND mode. Therefore, a new ECC circuit corresponding to the data transfer system of the PureNAND mode does not have to be provided outside or inside a chip. In consequence, it is possible to enhance data reliability in the PureNAND mode, while decreasing manufacturing cost of the memory system 1.

### Third Embodiment

In OneNAND mode and PureNAND mode, types of clocks are used. A clock generation circuit which generates the clock regulates a clock cycle by use of a delay circuit. A capacitor and a resistor for use in this delay circuit has a larger area as compared with a transistor, which is one of factors that disturb the reduction of a chip area. A third embodiment shares the delay circuit included in the clock generation circuit by the OneNAND mode and the PureNAND mode, to reduce the chip area.

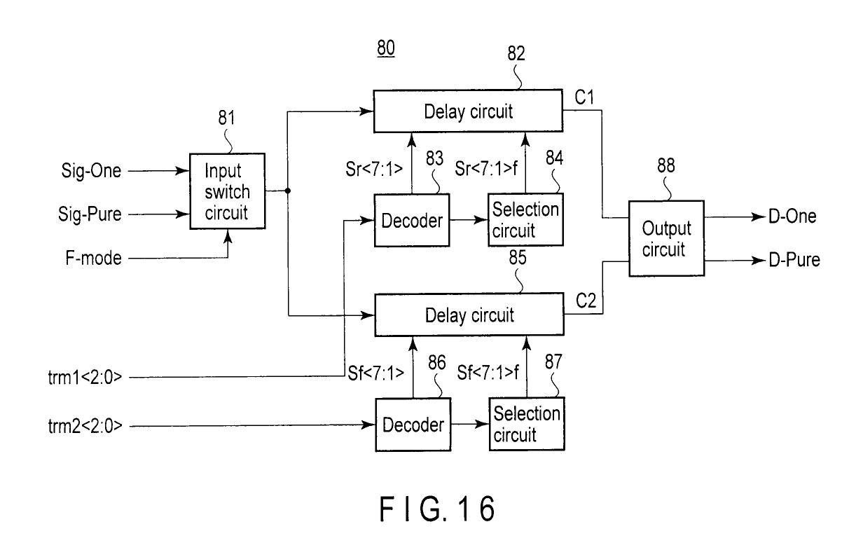

FIG. 16 is a block diagram of a clock generation circuit 80 according to the third embodiment. The clock generation circuit 80 includes an input switch circuit 81, two delay circuits 82 and 85, two decoders 83 and 86, selection circuits 84 and 87 and an output circuit 88.

The clock generation circuit 80 receives a clock Sig-One for the OneNAND mode, and generates a clock D-One by use of the clock Sig-One. Moreover, the clock generation circuit 80 receives a clock Sig-Pure for the PureNAND mode, and generates a clock D-Pure by use of the clock Sig-Pure.

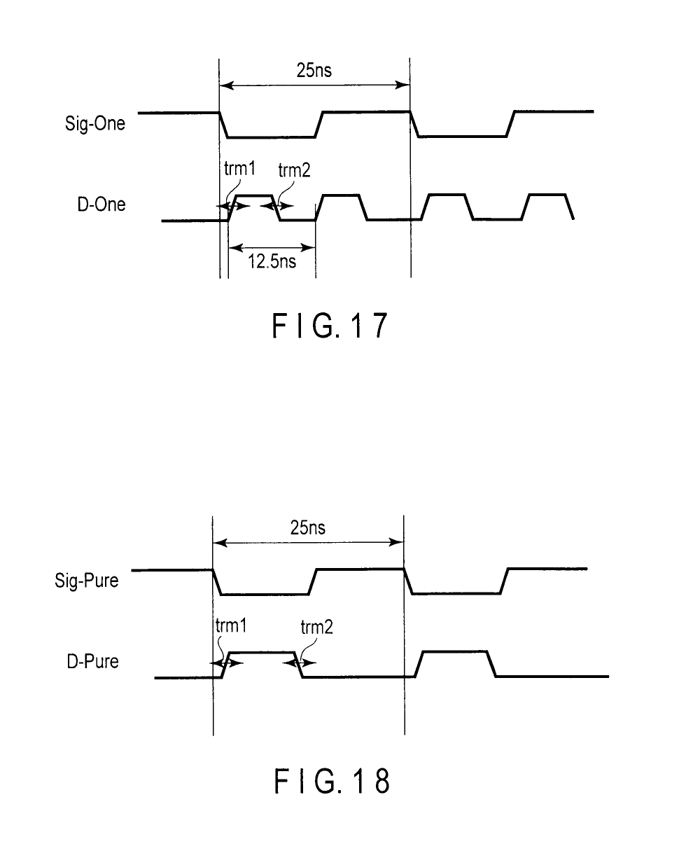

FIG. 17 is a diagram explaining the clock for the OneNAND mode. The clock Sig-One is a signal generated in a chip, and designed so as to operate with a cycle of 25 ns. The clock D-One is a signal generated from the clock Sig-One, and requested to operate with a cycle of 12.5 ns which is a half of the cycle of 25 ns, for the execution of the OneNAND mode. A correlation with the first embodiment will be described. The clock generation circuit 80 corresponds to the clock generation circuit 14c, or a circuit included in the clock generation circuit 14b to generate the clock CLK2c, and additionally includes a circuit which generates a clock for the PureNAND mode. The clock Sig-One corresponds to the clock CLK0 of FIG. 6. The clock D-One corresponds to the clocks CLK2c and CLK3 of FIG. 6.

FIG. 18 is a diagram explaining a clock for the PureNAND mode. The clock Sig-Pure is, for example, a signal input from the outside, and a cycle of the signal differs with specifications of a product, but the cycle is usually a 25-ns cycle. In the present embodiment, the cycle of the clock Sig-Pure is set to 25 ns. The clock D-Pure is a signal generated from the clock Sig-Pure, and requested to operate with a cycle of 25 ns, for the execution of the PureNAND mode. A correlation with the first embodiment will be described. The clock D-Pure is a clock for operating the second latch circuit 71B and the third latch circuit 72 of FIG. 3.

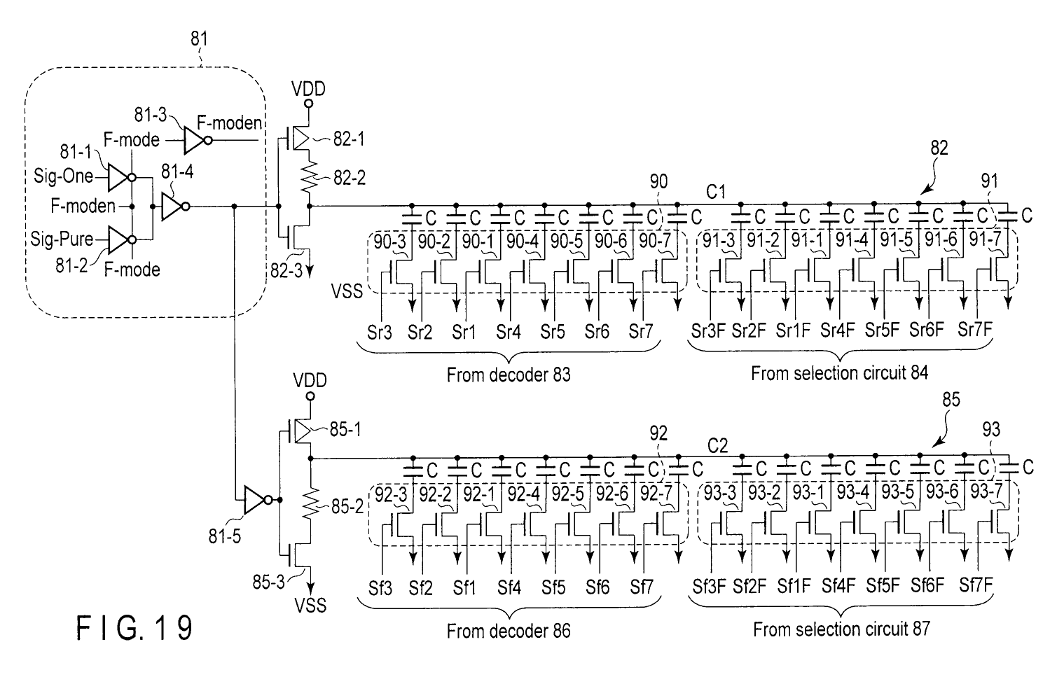

FIG. 19 is a circuit diagram of the input switch circuit 81 and the delay circuits 82 and 85. The input switch circuit 81 includes two clocked inverter circuits 81-1 and 81-2, and two inverter circuits 81-3 and 81-4.

To an input of the clocked inverter circuit 81-1, the clock Sig-One is supplied. An output of the clocked inverter circuit 81-1 is connected to an input of the inverter circuit 81-4. To an input of the clocked inverter circuit 81-2, the clock Sig-Pure is supplied. An output of the clocked inverter circuit 81-2 is connected to the input of the inverter circuit 81-4.

To an input of the inverter circuit 81-3, a signal F-mode for switching the OneNAND mode and the PureNAND mode is supplied. The inverter circuit 81-3 outputs an inversion signal F-moden of a signal F-mode. The signal F-mode is supplied from a controller 4. The signal F-mode becomes a low level in the OneNAND mode, and becomes a high level in the PureNAND mode. The clocked inverter circuit 81-1 operates in the OneNAND mode, and the clocked inverter circuit 81-2 operates in the PureNAND mode. Therefore, the clock Sig-One becomes valid in the OneNAND mode, and the clock Sig-Pure becomes valid in the PureNAND mode.

An output of the inverter circuit 81-4 is connected to an input of the delay circuit 82. Moreover, the output of the inverter circuit 81-4 is connected to an input of the delay circuit 85 via an inverter circuit 81-5.

The delay circuit 82 includes a P-channel metal oxide semiconductor field effect transistor (MOSFET) 82-1, a resistor 82-2, an N-channel MOSFET 82-3, 14 capacitors C, a selection transistor group 90, and a selection transistor group 91.

A source of the PMOSFET 82-1 is connected to a power supply terminal VDD, a gate thereof is connected to an output of the inverter circuit 81-4, and a drain thereof is connected to one end of the resistor 82-2. A drain of the NMOSFET 82-3 is connected to the other end of the resistor 82-2 via a node C1, a gate thereof is connected to the output of the inverter circuit 81-4, and a source thereof is connected to an earth terminal VSS.

The selection transistor group 90 is constituted of, for example, seven NMOSFETs 90-1 to 90-7. A drain of each of the NMOSFETs 90-1 to 90-7 is connected to one electrode of each of seven capacitors C. To gates of the NMOSFETs, selection signals Sr1 to Sr7 are supplied from the decoder 83, respectively, and sources of the NMOSFETs are connected to the earth terminal VSS, respectively. The other electrodes of the seven capacitors C connected to the selection transistor group 90 are connected to the node C1.

The selection transistor group 91 is constituted of, for example, seven NMOSFETs 91-1 to 91-7. A drain of each of the NMOSFETs 91-1 to 91-7 is connected to one electrode of each of the seven capacitors C. To gates of the NMOSFETs, selection signals SrF1 to SrF7 are supplied from the selection circuit 84, respectively, and sources of the NMOSFETs are connected to the earth terminal VSS, respectively. The other electrodes of the seven capacitors C connected to the selection transistor group 91 are connected to the node C1. The number of the capacitors C included in the delay circuit 82 can arbitrarily be set.

The delay circuit 85 includes a PMOSFET 85-1, a resistor 85-2, an N-channel MOSFET 85-3, 14 capacitors C, a selection transistor group 92, and a selection transistor group 93.

A source of the PMOSFET 85-1 is connected to a power supply terminal VDD, a gate thereof is connected to an output of the inverter circuit 81-5, and a drain thereof is connected to one end of the resistor 85-2. A drain of the NMOSFET 85-3 is connected to the other end of the resistor 85-2 via a node C2, a gate thereof is connected to the output of the inverter circuit 81-5, and a source thereof is connected to an earth terminal VSS.

The selection transistor group 92 is constituted of, for example, seven NMOSFETs 92-1 to 92-7. A drain of each of the NMOSFETs 92-1 to 92-7 is connected to one electrode of each of seven capacitors C. To gates of the NMOSFETs, selection signals Sf1 to Sf7 are supplied from the decoder 86, respectively, and sources of the NMOSFETs are connected to the earth terminal VSS, respectively. The other electrodes of the seven capacitors C connected to the selection transistor group 92 are connected to the node C2.

The selection transistor group 93 is constituted of, for example, seven NMOSFETs 93-1 to 93-7. A drain of each of the NMOSFETs 93-1 to 93-7 is connected to one electrode of each of the seven capacitors C. To gates of the NMOSFETs, selection signals SfF1 to SfF7 are supplied from the selection circuit 87, respectively, and sources of the NMOSFETs are connected to the earth terminal VSS, respectively. The other electrodes of the seven capacitors C connected to the selection transistor group 93 are connected to the node C2. The number of the capacitors C included in the delay circuit 85 can arbitrarily be set. All the capacitors C included in the delay circuits 82 and 85 have the same capacity.

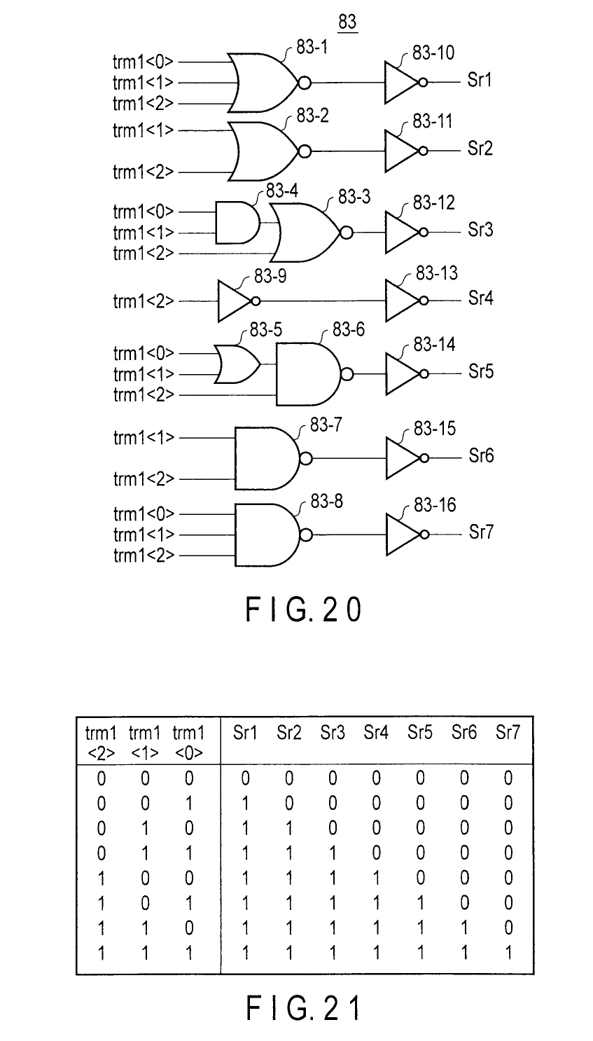

FIG. 20 is a circuit diagram of the decoder 83. The decoder 83 includes three NOR circuits 83-1 to 83-3, an AND circuit 83-4, an OR circuit 83-5, three NAND circuits 83-6 to 83-8, and eight inverter circuits 83-9 to 83-16.

The decoder 83 receives a trim signal trm1 <2:0> for regulating a timing of a clock, and decodes the trim signal trm1 <2:0> to generate the selection signals Sr1 to Sr7. The trim signal trm1 <2:0> is supplied from the controller 4. FIG. 21 is a diagram explaining a selection signal Sr. By the selection signal Sr, the number of the NMOSFETs to be turned on in the selection transistor group 90 can be controlled, so that a capacity of the node C1 can be controlled.

The decoder 86 has a constitution similar to the decoder 83, and can be realized by changing the trim signal trm1 <2:0> of FIG. 20 to trm2 <2:0> and changing the selection signal Sr to Sf.

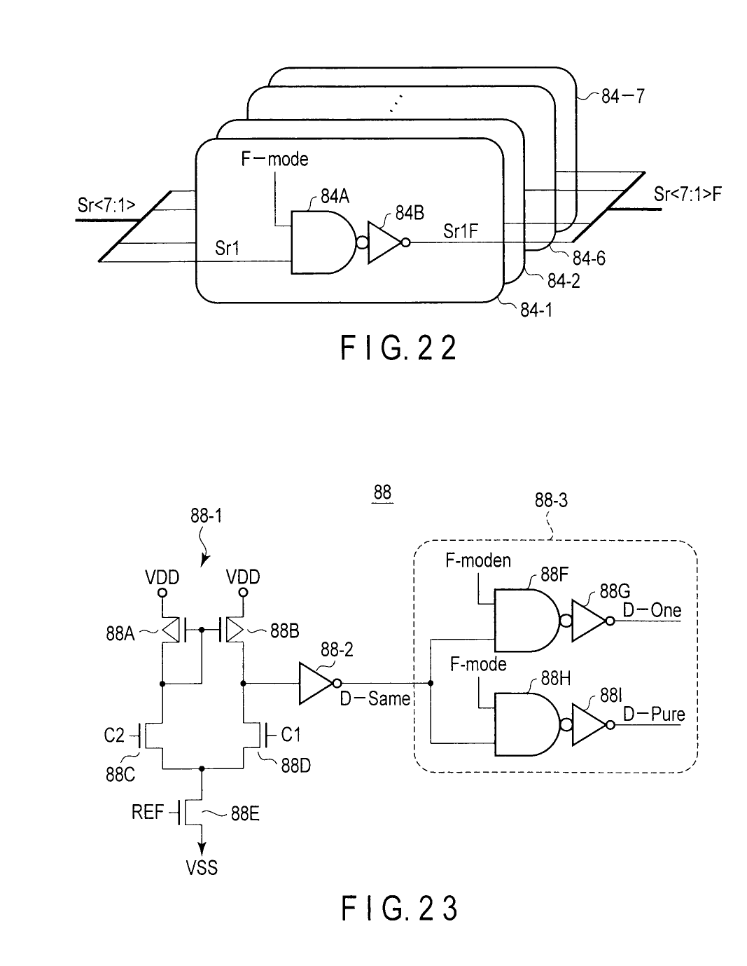

FIG. 22 is a circuit diagram of the selection circuit 84. The selection circuit 84 includes seven circuit portions 84-1 to 84-7 corresponding to the selection signals Sr, respectively. The circuit portion 84-1 includes a NAND circuit 84A and an inverter circuit 84B. To a first input of the NAND circuit 84A, the selection signal Sr1 is supplied. To a second input of the NAND circuit 84A, the signal F-mode is supplied. An output of the NAND circuit 84A is connected to an input of the inverter circuit 84B. The inverter circuit 84B outputs a selection signal Sr1F. Constitutions of the circuit portions 84-2 to 84-7 are the same as the constitution of the circuit portion 84-1. The selection circuit 84 activates a selection signal Sr<7:1>F, when the signal F-mode has a high level, i.e., in the PureNAND mode.

FIG. 23 is a circuit diagram of the output circuit 88. The output circuit 88 includes a differential amplifier 88-1, an inverter circuit 88-2, and an output selection circuit 88-3.

The differential amplifier 88-1 includes two PMOSFETs 88A and 88B, and three NMOSFETs 88C to 88E. A source of the PMOSFET 88A is connected to a power supply terminal VDD, and a gate thereof is connected to the source thereof and a drain of the NMOSFET 88C. A gate of the NMOSFET 88C is connected to the node C2 of the delay circuit 85, and a source thereof is connected to a drain of the NMOSFET 88E. To a gate of the NMOSFET 88E, a reference voltage REF is applied, and a source thereof is connected to an earth terminal VSS.

A source of the PMOSFET 88B is connected to a power supply terminal VDD, a gate thereof is connected to the gate of the PMOSFET 88A, and a drain thereof is connected to a drain of the NMOSFET 88D. A gate of the NMOSFET 88D is connected to the node C1 of the delay circuit 82, and a source thereof is connected to the drain of the NMOSFET 88E.

The differential amplifier 88-1 amplifies and outputs a voltage difference between the node C1 and the node C2. An output of the differential amplifier 88-1 is connected to an input of the inverter circuit 88-2. The inverter circuit 88-2 outputs a clock D-Same. The clock D-Same is supplied to the output switch circuit 88-3.

The output switch circuit 88-3 includes two NAND circuits 88F and 88H, and two inverter circuits 88G and 88I. To a first input of the NAND circuit 88F, the clock D-Same is supplied, and to a second input thereof, a signal F-moden is supplied. An output of the NAND circuit 88F is connected to an input of the inverter circuit 88G. The inverter circuit 88G outputs a clock D-One.

To a first input of the NAND circuit 88H, the clock D-Same is supplied, and to a second input thereof, a signal F-mode is supplied. An output of the NAND circuit 88H is connected to an input of the inverter circuit 88I. The inverter circuit 88I outputs a clock D-Pure.

The output switch circuit 88-3 outputs the clock D-Pure, when the signal F-mode has a high level, i.e., in the PureNAND mode. Moreover, the output switch circuit 88-3 outputs the clock D-One, when the signal F-mode has a low level, i.e., in the OneNAND mode.

Next, an operation of the clock generation circuit 80 having such a constitution will be described. The clock generation circuit 80 regulates delay time of the clock by a difference in capacity charge/discharge time between the node C1 and the node C2.

The OneNAND mode and the PureNAND mode have different required delay times, and hence the delay circuits 82 and 85 have a constitution in which the number of the capacitors C to be activated can be controlled in the OneNAND mode and the PureNAND mode.

The delay circuit 82 uses seven capacitors C connected to the selection transistor group 90 in the OneNAND mode, and uses 14 capacitors C connected to the selection transistor groups 90 and 91 in the PureNAND mode. Similarly, the delay circuit 85 uses seven capacitors C connected to the selection transistor group 92 in the OneNAND mode, and uses 14 capacitors C connected to the selection transistor groups 92 and 93 in the PureNAND mode. The number of the capacitors C for use in the PureNAND mode is larger than that in the OneNAND mode, because the clock D-Pure for the PureNAND mode has a longer cycle.

Moreover, when the trim signal trm1 <2:0> and the trim signal trm2 <2:0> are controlled in the OneNAND mode as shown in FIG. 17, timings of rising and falling of the clock D-One can be regulated. Similarly, when the trim signal trm1 <2:0> and the trim signal trm2 <2:0> are controlled in the PureNAND mode as shown in FIG. 18, timings of rising and falling of the clock D-Pure can be regulated.

As described above in detail, according to the third embodiment, one clock generation circuit 80 can generate the clock D-One with a cycle of 12.5 ns for the OneNAND mode and the clock D-Pure with a cycle of 25 ns for the PureNAND mode.

Moreover, the OneNAND mode and the PureNAND mode can share the capacitors and resistors constituting the delay circuits 82 and 85, and the decoders 83 and 86. On the other hand, when the capacitors, resistors and decoders are shared, the input switch circuit 81, the selection circuits 84 and 87 and the output switch circuit 88-3 need to be added. However, the capacitors, resistors and decoders occupy 80% of an area of the clock generation circuit 80, and most of the components can be shared, which has a large chip area saving effect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory; and
a data transfer section configured to perform data transfer from and to the memory, and having a first mode to transfer data with a first bit width and a second mode to transfer data with a second bit width,
the data transfer section including:
a first latch circuit configured to hold first data read from the memory;
a second latch circuit configured to hold second data having the first bit width of the first data in the first mode, and to hold third data having the second bit width of the first data in the second mode; and
data bus connecting the first latch circuit to the second latch circuit and shared by the first and second modes.

2. The device of claim 1, wherein the second latch circuit includes a first latch portion configured to hold the second data, and a second latch portion configured to hold the third data.

3. The device of claim 2, wherein
the first latch circuit takes in the first data in response to a first clock, and outputs data with the first bit width in response to a second clock, and
the first latch portion performs a holding operation in response to the second clock.

4. The device of claim 3, wherein
the first data has a bit width which is twice as much as the first bit width, and
a cycle of the first clock is twice as much as a cycle of the second clock.

5. The device of claim 2, wherein
the first latch portion is connected to an ECC section which corrects an error, and
the second latch portion is connected to an interface section which receives and transmits data from and to the outside.

6. The device of claim 2, wherein the data bus include a first data bus connected to the first latch portion, and a second data bus connected to the first latch portion and the second latch portion.

7. The device of claim 2, wherein the first bit width is twice as much as the second bit width.

8. The device of claim 3, further comprising a sequencer configured to generate the first and second clocks.

9. The device of claim 1, further comprising a clock generation circuit configured to generate a first clock for the first mode by use of a first reference clock, and to generate a second clock for the second mode by use of a second reference clock.

10. The device of claim 9, wherein the clock generation circuit includes a delay circuit configured to regulate delay times of the first and second reference clocks, and shared by the first and second modes.

11. The device of claim 10, wherein the delay circuit includes capacitors and resistors.

12. The device of claim 1, further comprising an SRAM,
wherein in the first mode, the data transfer is performed via the SRAM.

13. The device of claim 1, wherein the memory is a NAND flash memory.

14. The device of claim 13, further comprising a page buffer provided between the NAND flash memory and the data transfer section.

15. A semiconductor memory device comprising:
a memory;
a page buffer configured to read data from the memory for each page, and to store read data read from the memory;
an ECC section configured to correct an error in the read data transferred from the page buffer, and to write back the corrected read data to the page buffer; and
an interface section configured to output the read data written back to the page buffer.

16. The device of claim 15, wherein
the page buffer stores write data input into the interface section, and
the ECC section generates parity data for the write data transferred from the page buffer, and writes back the parity data and the write data to the page buffer.

17. The device of claim 15, further comprising a controller configured to perform a first mode to transfer data with a first bit width and a second mode to transfer data with a second bit width,
wherein the ECC section is shared by the first and second modes.

18. The device of claim 17, further comprising an SRAM,
wherein in the first mode, the data transfer is performed via the SRAM.

19. The device of claim 17, wherein the first bit width is twice as much as the second bit width.

20. The device of claim 15, wherein the memory is a NAND flash memory.
